(19) United States
(12) Patent Application Publication
(10) Pub. No.: US 2012/0168815 A1
(43) Pub. Date: Jul. 5, 2012

(54) ENCAPSULATION MATERIAL AND ELECTRONIC DEVICE PREPARED USING THE SAME

(76) Inventors: Sang-Ran Koh, Uiwang-si (KR); Yong Kook Kim, Uiwang-si (KR); Woo-Han Kim, Uiwang-si (KR); Ha Neul Kim, Uiwang-si (KR); Chi Won An, Uiwang-si (KR); Sung-Hwan Cha, Uiwang-si (KR)

(21) Appl. No.: 13/338,549

(22) Filed: Dec. 28, 2011

(30) Foreign Application Priority Data
Dec. 31, 2010 (KR) 10-2010-0140559

(51) Int. Cl. H01L 33/52; H01B 1/20; B82Y 30/00

(52) U.S. Cl. 257/100; 252/500; 252/519.31; 977/774; 257/E33.059

(57) ABSTRACT

An encapsulation material and an electronic device, the encapsulation material including a resin, the resin including a first polysiloxane including hydrogen bonded with silicon (Si—H) at a terminal end thereof, and a second polysiloxane including an alkenyl group bonded with silicon (Si-Vi) at a terminal end thereof, a phosphor, and a density controlling agent, wherein a weight ratio of the density controlling agent to the phosphor is about 1.5:1 to about 10:1.

### BACKGROUND

1. Field

Embodiments relate to an encapsulation material and an electronic device prepared using the same.

2. Description of the Related Art

A light emitting element, e.g., a light emitting diode (LED), an organic light emitting device (OLED), a photoluminescent (PL) device, and the like, may be applied to diverse areas, e.g., a domestic electric device, a lighting device, a display device, various automatic devices, and the like.

In some cases, the light emitting element may display intrinsic colors of a light emitting material, e.g., blue, red, and green in a light emitting region, or white by combining light emitting regions displaying different colors. This light emitting element may generally include an encapsulant having a packaging or encapsulation structure. Such an encapsulant may be formed from a resin that is able to externally pass light emitted from a light emitting region.

The encapsulant may include phosphors that display or emit a predetermined color of light. For example, the phosphors may receive energy from the light that is emitted from a light emitting region and may display a predetermined color by emitting light having a longer wavelength than that of the light emitted from the light emitting region.

### SUMMARY

Embodiments are directed to an encapsulation material and an electronic device prepared using the same.

The embodiments may be realized by providing an encapsulation material including a resin, the resin including a first polysiloxane including hydrogen bonded with silicon (Si—H) at a terminal end thereof, and a second polysiloxane including an alkenyl group bonded with silicon (Si-Vi) at a terminal end thereof, a phosphor, and a density controlling agent, wherein a weight ratio of the density controlling agent to the phosphor is about 1.5:1 to about 10:1.

The density controlling agent may have a higher density than the first polysiloxane and the second polysiloxane.

The density controlling agent may include silica, a metal oxide, or a combination thereof.

The density controlling agent may include the metal oxide, the metal oxide including titanium oxide, zinc oxide, aluminum oxide, or a combination thereof.

The encapsulation material may further include a dispersion aid.

The dispersion aid may include a silane-based compound, a (meth)acryl-based compound, or a combination thereof.

The dispersion aid may include trimethoxysilane, glycidyloxypropyl trimethoxysilane, mercaptopropyl trimethoxysilane, epoxycyclohexyl ethyl trimethoxysilane, trimethoxy (7-octen-1-yl)silane, oxabicyclo[4.1.0]hept-3-yl)ethyl]silane, methyltrimethoxysilane, phenyltrimethoxysilane, vinyltrimethoxysilane, allyltrimethoxysilane, 3-(trimethoxysilyl)propyl (meth)acrylate, or a combination thereof.

The dispersion aid may be included in an amount of about 0.01 to about 5 wt %, based on a total weight of the encapsulation material.

The first polysiloxane may be represented by the following Chemical Formula 1:

(R₁R₂R₃SiO_{1/2})_{M1}(R₄R₅SiO_{2/2})_{D1}(R₆SiO_{3/2})_{T1}(SiO_{4/2})_{Q1},

in Chemical Formula 1 R₁ to R₆ may each independently be hydrogen, a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof, at least one of R₁ to R₆ may be hydrogen, 0<M1<1, 0≦D1<1, 0≦T1<1, 0≦Q1<1, and M1+D1+T1+Q1=1.

The second polysiloxane may be represented by the following Chemical Formula 2:

(R₇R₈R₉SiO_{1/2})_{M2}(R₁₀R₁₁SiO_{2/2})_{D2}(R₁₂SiO_{3/2})_{T2}(SiO_{4/2})_{Q2}, [Chemical Formula 2]

in Chemical Formula 2 R₇ to R₁₂ may each independently be substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof, at least one of R₇ to R₁₂ may be a substituted or unsubstituted C2 to C30 alkenyl group, 0<M2<1, 0≦D2<1, 0≦T2<1, 0≦Q2<1, and M2+D2+T2+Q2=1.

The first polysiloxane may be included in an amount of less than about 50 wt % of a total weight of the resin, and the second polysiloxane may be included in an amount of more than about 50 wt % of a total weight of the resin.

The embodiments may also be realized by providing an electronic device including an encapsulant prepared by curing the encapsulation material according to an embodiment.

The electronic device may include a light emitting region that emits light having a shorter wavelength than light emitted by the phosphor.

The device may display white color light by combining light emitted from the light emitting region and the phosphor.

The light emitting region may include one of a light emitting diode and an organic light emitting device.

The encapsulant may include silica, a metal oxide, or a combination thereof, and a weight ratio of the silica, the metal oxide, or the combination thereof to the phosphor may be about 1.5:1 to about 10:1.

### BRIEF DESCRIPTION OF THE DRAWING

The embodiments will become more apparent to those of ordinary skill in the art by describing in detail exemplary embodiments with reference to the attached drawing, in which:

FIG. 1 illustrates a schematic cross-sectional view of a light emitting diode according to an embodiment.

### DETAILED DESCRIPTION

Korean Patent Application No. 10-2010-0140559, filed on Dec. 31, 2010, in the Korean Intellectual Property Office, and entitled: “Encapsulation Material and Electronic Device Including the Same,” is incorporated by reference herein in its entirety.

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figure, the dimensions of layers and regions may be exaggerated for clarity of illustration. It will also be understood that when a layer or element is referred to as being “on” another layer or substrate, it can be directly on the other layer or substrate, or intervening layers may also be present. Like reference numerals refer to like elements throughout.

As used herein, when a definition is not otherwise provided, the term “substituted” may refer to one substituted with at least a substituent selected from the group consisting of a halogen (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, an alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof, instead of hydrogen of a compound.

As used herein, when a definition is not otherwise provided, the prefix “hetero” may refer to one including 1 to 3 heteroatoms selected from N, O, S, and P.

Hereinafter, an encapsulation material according to an embodiment is described.

The encapsulation material according to an embodiment may include a resin (including a first polysiloxane having hydrogen bonded with silicon (Si—H) at a terminal end thereof and a second polysiloxane having an alkenyl group bonded with silicon (Si-Vi) at a terminal end thereof); a phosphor; and a density controlling agent.

The first polysiloxane may be represented by the following Chemical Formula 1.

(R₁R₂R₃SiO_{1/2})_{M1}(R₄R₅SiO_{2/2})_{D1}(R₆SiO_{3/2})_{T1}(SiO_{4/2})_{Q1} [Chemical Formula 1]

In Chemical Formula 1, R₁ to R₆ may each independently be hydrogen, a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof. In an implementation, at least one of R₁ to R₆ may be hydrogen.

M1, D1, T1, and Q1 may satisfy the relations: 0<M1<1, 0≦D1<1, 0≦T1<1, 0≦Q1<1, and M1+D1+T1+Q1=1, where M1, D1, T1, and Q1 denote each mole ratio.

In an implementation, the first polysiloxane may have, on average, at least two silicon-hydrogen bonds (Si—H) in each molecule, and an aryl group bonded with silicon atoms.

The first polysiloxane may be obtained by copolymerizing a monomer represented by the following Chemical Formula 1a and at least one of the monomers represented by the following Chemical Formula 1b, the following Chemical Formula 1c, and the following Chemical Formula 1d.

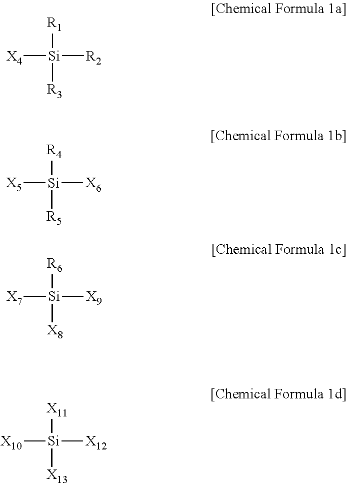

In Chemical Formulae 1a to 1d, R₁ to R₆ may each independently be hydrogen, a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof. X₁ to X₁₃ may each independently be a C1 to C6 alkoxy group, a hydroxy group, a halogen, a carboxyl group, or a combination thereof. In an implementation, at least one of R₁ to R₆ may be hydrogen. In an implementation, a bond between Si and R₁ to R₆ may be a carbon-silicon bond.

Alternatively, the first polysiloxane may be obtained by a reaction of at least one of the monomers represented by the Chemical Formula 1a, the Chemical Formula 1b, the Chemical Formula 1c, and the Chemical Formula 1d, and HRₐR_{b}Si—O—Si—R_{c}R_{d}H. Herein, Rₐ, R_{b}, R_{c}, and R_{d} may each independently be a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof. X₁ to X₁₃ may each independently be a C1 to C6 alkoxy group, a hydroxy group, a halogen, a carboxyl group, or a combination thereof.

The first polysiloxane may have a weight average molecular weight of about 100 g/mol to about 30,000 g/mol, e.g., about 100 g/mol to about 10,000 g/mol.

The first polysiloxane may be present in an amount of less than about 50 wt %, e.g., about 1 to about 35 wt %, of a total weight of the resin.

The second polysiloxane may be represented by the following Chemical Formula 2.

(R₇R₈R₉SiO_{1/2})_{M2}(R₁₀R₁₁SiO_{2/2})_{D2}(R₁₂SiO_{3/2})_{T2}(SiO_{4/2})_{Q2} [Chemical Formula 2]

In Chemical Formula 2, R₇ to R₁₂ may each independently be a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof. In an implementation, at least one of R₇ to R₁₂ may be a substituted or unsubstituted C2 to C30 alkenyl group. In an implementation, a bond between Si and R₇ to R₁₂ may be a carbon-silicon bond.

M2, D2, T2, and Q2 may satisfy the relations: 0<M2<1, 0≦D2<1, 0≦T2<1, 0≦Q2<1, and M2+D2+T2+Q2=1, where M2, D2, T2, and Q2 denote each mole ratio.

In an implementation, the second polysiloxane may include, on average, two or more alkenyl group bonded with silicon (Si-Vi) in each molecule.

The second polysiloxane may be obtained by copolymerizing a monomer represented by the following Chemical Formula 2a (or a corresponding dimer thereof), and at least one of the monomers represented by the following Chemical Formula the following Chemical Formula 2b, the following Chemical Formula 2c, and the following Chemical Formula 2d.

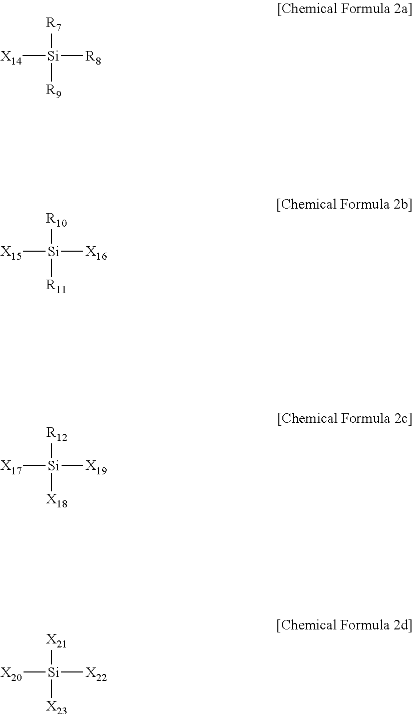

In Chemical Formulae 2a to 2d, R₇ to R₁₂ may each independently be a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof. X₁₄ to X₂₃ may each independently be a C1 to C6 alkoxy group, a hydroxyl group, a halogen, a carboxyl group, or a combination thereof. In an implementation, at least one of R₇ to R₁₂ may be a substituted or unsubstituted C2 to C30 alkenyl group.

Alternatively, the second polysiloxane may be obtained by a reaction of at least one of the monomers represented by the Chemical Formula 2a, the Chemical Formula 2b, the Chemical Formula 2c, and the Chemical Formula 2d, and ViRₑR_{f}Si—O—S₁—R_{g}RₕVi. Herein, Rₑ, R_{f}, R_{g}, and Rₕ may each independently be a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof. X₁ to X₁₃ may each independently be a C1 to C6 alkoxy group, a hydroxy group, a halogen, a carboxyl group, or a combination thereof.

The second polysiloxane may have a weight average molecular weight about 100 g/mol to about 30,000 g/mol, e.g., about 100 g/mol to about 10,000 g/mol.

The second polysiloxane may be present in an amount of more than about 50 wt %, e.g., about 65 to about 99 wt %, based on the total weight of the resin.

With the first polysiloxane (including hydrogen bonded with silicon (Si—H) at the terminal end thereof) and the second polysiloxane (including an alkenyl group bonded with silicon (Si-Vi) at the terminal end thereof), extents of the cross-linking and curing of a resin may be controlled.

The phosphors may include a material that is stimulated by light and emits light of an intrinsic wavelength range by itself. Phosphors includes a quantum dot, e.g., a semiconductor nanocrystal, in its broad meaning.

The phosphors may include, e.g., blue phosphors (emitting blue light), green phosphors (emitting green light), or red phosphors (emitting red light), or the phosphors may include a mixture of two or more kinds of phosphors.

The phosphors may emit light of a predetermined wavelength in response to the light emitted from a light emitting region in a light emitting device. Herein, the light emitting region may emit light having a shorter wavelength than the light emitted by the phosphors. For example, when the phosphors emit red light, the light emitting region may emit light having a shorter wavelength than the red light, e.g., blue light or green light.

The electronic device may display white light by combining colors of light emitted from the light emitting region and the phosphors. For example, when the light emitting region emits blue light and the phosphors include red phosphors (emitting red light) and green phosphors (emitting green light), the electronic device may display white colored light by combining the blue light, red light, and green light.

The density controlling agent may help control a density difference between the resin (including the first polysiloxane and the second polysiloxane) and the phosphors. In an implementation, the density controlling agent may help uniformly disperse the phosphors in the resin.

For example, in a liquid encapsulation material (before curing), the resin (including the first polysiloxane and the second polysiloxane) may have a density of about 0.8 to about 1.5, while the phosphors may have a density of about 2.5 to about 4.

Accordingly, the resin and the phosphors may have a density difference. Thus, the phosphors may not be uniformly dispersed in the resin. For example, the phosphors may be distributed to a greater degree toward a lower part of the resin. When the liquid encapsulation material is cured, an encapsulant may include more phosphors in the lower part an fewer phosphors in the upper part. Thus, the encapsulant may exhibit deteriorated color uniformity and color reproducibility. In addition, the phosphors may not be uniformly distributed in the resin. Thus, light emitting characteristics, e.g., luminance, may be deteriorated.

The density controlling agent may have a higher density than the first polysiloxane and the second polysiloxane. Thus, the density controlling agent may bolster low density of the first polysiloxane and the second polysiloxane and may help ensure that phosphors (having a relatively high density) are uniformly distributed in the resin.

The density controlling agent may include or be made of, e.g., silica, metal oxide, or a combination thereof. The metal oxide may include, e.g., titanium oxide, zinc oxide, aluminum oxide, or a combination thereof.

The density controlling agent may be variously included in view of density differences between the resin (including the first polysiloxane and the second polysiloxane) and the phosphors. In an implementation, a weight ratio of the density controlling agent to the phosphors may be about 1.5:1 to about 10:1.

Maintaining the weight ratio of the density controlling agent to the phosphors within this range may help ensure that the density controlling agent balances density between the resin and the phosphors, and that the phosphors are uniformly distributed in the resin. Accordingly, the density controlling agent may help increase distribution uniformity of the phosphors in the resin and thereby help improve color and light emitting characteristics.

The encapsulation material may further include a dispersion aid. The dispersion aid may modify a surface of the density controlling agent from having hydrophilic properties to having hydrophobic properties. Thus, dispersion of the density controlling agent may be improved.

The dispersion aid may include, e.g., a silane-based compound, a (meth)acryl-based compound, or a combination thereof. In an implementation, the dispersion aid may include, e.g., trimethoxysilane, glycidyloxypropyl trimethoxysilane, mercaptopropyl trimethoxysilane, epoxycyclohexyl ethyl trimethoxysilane, trimethoxy (7-octen-1-yl)silane, oxabicyclo([4.1.0]hept-3-yl)ethylsilane, methyltrimethoxysilane, phenyltrimethoxysilane, vinyltrimethoxysilane, allyltrimethoxysilane, 3-(trimethoxysilyl)propyl (meth)acrylate, or a combination thereof.

The dispersion aid may be included in an amount of about 0.01 to about 5 wt %, based on the total weight of the encapsulation material. When the dispersion aid is included within this range, the dispersion aid may help ensure that the density controlling agent is uniformly dispersed in the encapsulation material.

The encapsulation material may further include a hydrosilation catalyst. The hydrosilation catalyst may promote a hydrosilation reaction between the first polysiloxane and the second polysiloxane. For example, the hydrosilation catalyst may include platinum, rhodium, palladium, ruthenium, iridium or a combination thereof. The hydrosilation catalyst may be used to promote a hydrosilation reaction between the Si—H moiety of the first polysiloxane and the unsaturated bond of the alkenyl of the Si-Vi moiety of the second polysiloxane.

The hydrosilylation catalyst may be included in an amount of about 0.1 ppm to about 1,000 ppm, based on a total amount of the encapsulation material.

The encapsulation material may further include an adhesion promoter, in addition to the components described above. In an implementation, the adhesion promoter may include, e.g., glycidoxypropyltrimethoxysilane, vinyltriethoxysilane, glycidoxypropyltriethoxysilane, and the like.

The encapsulation material may be cured and may be used as an encapsulant of the electronic device. The electronic device may include, e.g., a light emitting diode (such as a p-n light emitting diode) and/or an organic light emitting device.

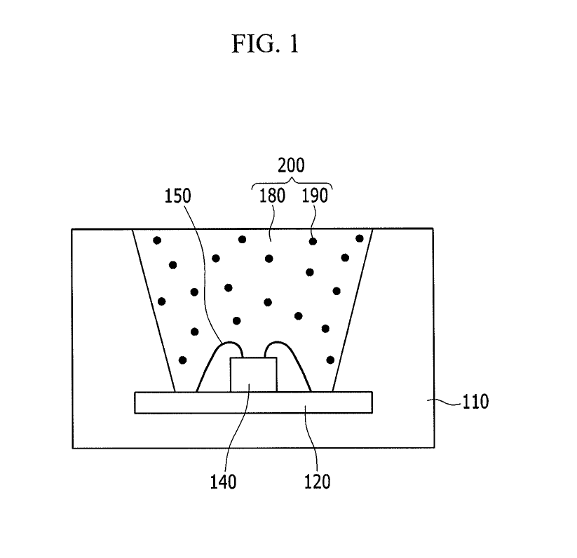

Hereafter, a light emitting diode according to an embodiment is described with reference to FIG. 1 as an example of an electronic device employing the encapsulation material. FIG. 1 illustrates a schematic cross-sectional view of a light emitting diode according to an embodiment.

Referring to FIG. 1, the light emitting diode may include a mold 110; a lead frame 120 disposed in the inside of the mold 110; a light emitting diode chip 140 mounted on the lead frame 120; a bonding wire 150 connecting the lead frame 120 and the light emitting diode chip 140; and an encapsulant 200 covering the light emitting diode chip 140.

The encapsulant 200 may be formed by curing the above-described encapsulation material, and may include a cured resin 180 (containing the first polysiloxane and the second polysiloxane) and phosphors 190.

The phosphors 190 may emit light of a predetermined wavelength in response to light emitted from the light emitting diode chip 140, which is a light emitting region. Herein, the light emitting diode chip 140 may emit light of a single wavelength different from the light emitted by the phosphors 190. For example, when the phosphors 190 emit red light, the light emitting diode chip 140 may emit blue light or green light, i.e., light of a shorter wavelength than the red light.

Also, white light may be displayed by combining the light emitted from the light emitting diode chip 140 and the light emitted from the phosphors 190. For example, when the light emitting diode chip 140 emits blue light and the phosphor 190 includes red phosphors and green phosphors, e.g., the phosphors 190 emit red light and green light, the light emitting diode may be a white light emitting diode that displays a white light by combining the blue, red, and green light.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

Synthesis of First Polysiloxane

Water and toluene were mixed in a weight ratio 5:5 to prepare a mixed solvent. 1 kg of the mixed solvent was put into a 3-necked flask, and 159.39 g of diphenyl dichlorosilane and 402 g of tetramethyldisiloxane as monomers were added dropwise thereto for 2 hours, while the flask was maintained at 23° C. When the dropwise addition was complete, the mixture was heated and refluxed to perform a condensation polymerization reaction at 90° C. for 3 hours. The resulting reactant was cooled down to room temperature, and a water layer therein was removed, preparing a solution in which a polymer was dissolved in toluene. The polymer solution was cleaned with water to remove chlorine, a reaction byproduct. Then, the neutralized polymer solution was distilled under reduced pressure to remove toluene, preparing liquid polysiloxane.

The polysiloxane was measured regarding weight average molecular weight through gel permeation chromatography and the molecular weight reduced to polystyrene was determined to be 350 g/mol. The polysiloxane was identified to have a structure of Chemical Formula 1-A using H-NMR, Si-NMR, and element analyzer. Herein, “Me” indicates a methyl group, “Ph” indicates a phenyl group, “Si” indicates silicon, and “H” indicates hydrogen.

(Me₂HSiO_{1/2})_{0.66}(Ph₂SiO_{2/2})_{0.33} [Chemical Formula 1-A]

Synthesis of Second Polysiloxane

1 kg of a mixed solvent prepared by mixing water and toluene at a weight ratio of 5:5 was put into a 3-neck flask and then, allowed to stand at 23° C. Subsequently, 372 g of phenylmethyldimethoxysilane, 372 g of divinyltetramethyldisiloxane, and 18 g of H₂O were mixed therewith at 25° C. The mixture was heated and refluxed to perform a condensation polymerization reaction at 90° C. for 3 hours. The resulting reactant was cooled down to room temperature, and a water layer therein was removed, preparing a solution in which a polymer was dissolved in toluene. The polymer solution was cleaned with water to remove chlorine, a reaction byproduct. Subsequently, the neutralized polymer solution was distilled under a reduced pressure to remove toluene and obtain liquid polysiloxane.

The obtained polysiloxane was measured regarding weight average molecular weight through a gel permeation chromatography, and was determined to have a molecular weight reduced to polystyrene of 6,000 g/mol. The polysiloxane was determined to have a structure represented by Chemical Formula 2-A using H-NMR, Si—NMR, and an element analyzer. Herein, “Me” indicates a methyl group; “Ph” indicates a phenyl group; “Vi” indicates a vinyl group; “Si” indicates silicon, and n is number such that the polysiloxane represented by Chemical Formula 2-A has the weight average molecular weight of 6,000 g/mol.

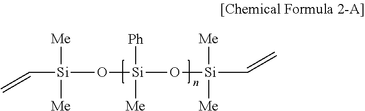

### Preparation of Encapsulation Material

### Example 1

30.5 wt % of the first polysiloxane represented by the above Chemical Formula 1-A, 69 wt % of the second polysiloxane represented by the above Chemical Formula 2-A, a hydrosilation catalyst Pt-CS 2.0 (Unicore Ltd.) (the reaction solution had a Pt concentration of 5 ppm), 0.5 wt % of aluminum oxide (Al₂O₃) (about 1.67 times the weight of phosphor to be added) as a density controlling agent, and 1 parts by weight (based on 100 parts by weight of total amount of the first polysiloxane, the second polysiloxane, and the density controlling agent) of vinyltrimethoxysilane as a dispersion aid were mixed, and 0.3 parts by weight (based on 100 parts by weight of total amount of the first polysiloxane, the second polysiloxane, and the density controlling agent) of phosphor was added thereto. Then, foam was removed from the mixture under a vacuum, preparing a liquid encapsulation material.

### Example 2

30.3 wt % of the first polysiloxane represented by the above Chemical Formula 1-A, 68.7 wt % of the second polysiloxane represented by the above Chemical Formula 2-A, a hydrosilation catalyst Pt-CS 2.0 (Unicore Ltd.) (the reaction solution had a Pt concentration of 5 ppm), 1 wt % of aluminum oxide (Al₂O₃) as a density controlling agent (about 3.33 times the weight of phosphor to be added), and 0 parts by weight (based on 100 parts by weight of total amount of the first polysiloxane, the second polysiloxane, and the density controlling agent) of vinyltrimethoxysilane as a dispersion aid were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

### Example 3

30.3 wt % of the first polysiloxane represented by the above Chemical Formula 1-A, 68.7 wt % of the second polysiloxane represented by the above Chemical Formula 2-A, a hydrosilation catalyst Pt-CS 2.0 (Unicore Ltd.) (the reaction solution had a Pt concentration of 5 ppm), 1 wt % of aluminum oxide (Al₂O₃) (about 3.33 times the weight of phosphor to be added) as a density controlling agent, and 1 parts by weight (based on 100 parts by weight of total amount of the first polysiloxane, the second polysiloxane, and the density controlling agent) of vinyltrimethoxysilane as a dispersion aid were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

### Example 4

30 wt % of the first polysiloxane represented by the above Chemical Formula 1-A, 68 wt % of the second polysiloxane represented by the above Chemical Formula 2-A, a hydrosilation catalyst Pt-CS 2.0 (Unicore Ltd.) (the reaction solution had a Pt concentration of 5 ppm), 2 wt % of aluminum oxide (Al₂O₃) (about 6.67 times the weight of phosphor to be added) as a density controlling agent, and 0 parts by weight (based on 100 parts by weight of total amount of the first polysiloxane, the second polysiloxane, and the density controlling agent) of vinyltrimethoxysilane as a dispersion aid were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

### Example 5

28 wt % of the first polysiloxane represented by the above Chemical Formula 1-A, 70 wt % of the second polysiloxane represented by the above Chemical Formula 2-A, a hydrosilation catalyst Pt-CS 2.0 (Unicore Ltd.) (the reaction solution had a Pt concentration of 5 ppm), 2 wt % of aluminum oxide (Al₂O₃) (about 6.67 times the weight of phosphor to be added) as a density controlling agent, and 1 parts by weight (based on 100 parts by weight of total amount of the first polysiloxane, the second polysiloxane, and the density controlling agent) of vinyltrimethoxysilane as a dispersion aid were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

### Example 6

28 wt % of the first polysiloxane represented by the above Chemical Formula 1-A, 69 wt % of the second polysiloxane represented by the above Chemical Formula 2-A, a hydrosilation catalyst Pt-CS 2.0 (Unicore Ltd.) (the reaction solution had a Pt concentration of 5 ppm), 3 wt % of aluminum oxide (Al₂O₃) (about 10 times times the weight of phosphor to be added) as a density controlling agent, and 0 parts by weight (based on 100 parts by weight of total amount of the first polysiloxane, the second polysiloxane, and the density controlling agent) of vinyltrimethoxysilane as a dispersion aid were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

### Example 7

28 wt % of the first polysiloxane represented by the above Chemical Formula 1-A, 69 wt % of the second polysiloxane represented by the above Chemical Formula 2-A, a hydrosilation catalyst Pt-CS 2.0 (Unicore Ltd.) (the reaction solution had a Pt concentration of 5 ppm), 3 wt % of aluminum oxide (Al₂O₃) (about 10 times times the weight of phosphor to be added) as a density controlling agent, and 1 parts by weight (based on 100 parts by weight of total amount of the first polysiloxane, the second polysiloxane, and the density controlling agent) of vinyltrimethoxysilane as a dispersion aid were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

### Comparative Example 1

30 wt % of the first polysiloxane represented by the above Chemical Formula 1-A, 70 wt % of the second polysiloxane represented by the above Chemical Formula 2-A, and a hydrosilation catalyst Pt-CS 2.0 (Unicore Ltd.) (the reaction solution had a Pt concentration of 5 ppm) were mixed, and 0.3 parts by weight of phosphor (based on 100 parts by weight of total amount of the first polysiloxane, the second polysiloxane, and the density controlling agent) of phosphor was added thereto. Then, foam was removed from the mixture under a vacuum, preparing an encapsulation material.

Evaluation—1

The encapsulation materials according to Examples 1 to 7 and Comparative Example 1 were measured regarding refractive index under a D-line 589 nm wavelength using an Abbe refractive index meter. The measurement results are shown in Table 1.

TABLE 1

| | | | | | | | | Comparative |
|---|---|---|---|---|---|---|---|---|
| | Example 1 | Example 2 | Example 3 | Example 4 | Example 5 | Example 6 | Example 7 | Example 1 |
| Refractive | 1.53 | 1.53 | 1.53 | 1.54 | 1.54 | 1.55 | 1.55 | 1.53 |
| index | | | | | | | | |

As shown in Table 1, the encapsulation materials according to Examples 1 to 7 had a similar refractive index to the encapsulation material according to Comparative Example 1. Accordingly, a density controlling agent and a dispersion controlling agent had no influence on the refractive index of the encapsulation materials according to Examples 1 to 7.

Evaluation—2

The encapsulation materials according to Examples 1 to 7 and Comparative Example 1 were injected into a mold (including a light emitting diode chip) with a syringe injector. Subsequently, thermal curing was performed at 150° C. for 2 hours to form an encapsulation layer. The color uniformity and light efficiency of the encapsulation layer were measured.

Color uniformity was measured based on a range of an x value in the color coordinates. When it is assumed that the range of the x value in the color coordinates of a color emitted from a light emitting diode using the encapsulation material prepared according to Comparative Example 1 was 1 (ref.), the ranges of the x values in the color coordinates of the colors emitted from the light emitting diodes using the encapsulation materials prepared according to Examples 1 to 7 were represented relatively. As the color uniformity is more uniform, e.g., an x value is within a narrow range, a similar color is displayed. Therefore, the color uniformity is high.

Light efficiency was measured using a spectroradiometer. When it is assumed that the light efficiency of the light emitting diode using the encapsulation material of Comparative Example 1 was 100% (ref.), the light efficiencies of the light emitting diodes respectively using the encapsulation materials according to Examples 1 to 7 were represented relatively. The measurement results are shown in Table 2.

TABLE 2

| | | | | | | | | Comparative |
|---|---|---|---|---|---|---|---|---|
| | Example 1 | Example 2 | Example 3 | Example 4 | Example 5 | Example 6 | Example 7 | Example 1 |
| Color | 0.90 | 0.90 | 0.80 | 0.90 | 0.71 | 0.95 | 0.73 | 1 (ref) |
| uniformity | | | | | | | | |
| Photo-efficiency | 100.5 | 100.6 | 102.1 | 101.0 | 105.2 | 106.0 | 108.1 | 100 (ref) |
| (%) | | | | | | | | |

Table 2 shows that the light emitting diodes prepared using the encapsulation materials prepared according to Examples 1 to 7 had excellent color uniformity as well as higher light efficiency than the light emitting diode prepared using the encapsulation material prepared according to Comparative Example 1.

In addition, the encapsulation material including the high amount of a density controlling agent as well as a dispersion aid (according to Example 7) had a narrow color coordinate region of about 70% and thus, much improved color uniformity and more than about 8% improved light efficiency, compared with the encapsulation material according to Comparative Example 1. Therefore, the encapsulation material according to the present embodiments had much improved color uniformity and light efficiency.

By way of summation and review, during processing of the encapsulant, uniform distribution of phosphors in a resin (despite density differences between the phosphors and the resin) is desirable. Thus, deterioration of color uniformity and light emitting characteristics may be reduced and/or prevented. In addition, color stains in a predetermined position or display of a different color (caused by non-uniform distribution of the phosphors) may be reduced and/or prevented.

The embodiments provide an encapsulation material having good color uniformity and light emitting characteristics.

An electronic device according to an embodiment may exhibit improved color characteristics and light emitting characteristics without affecting physical characteristics of the encapsulation material.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. An encapsulation material, comprising:
a resin, the resin including:
a first polysiloxane including hydrogen bonded with silicon (Si—H) at a terminal end thereof, and
a second polysiloxane including an alkenyl group bonded with silicon (Si-Vi) at a terminal end thereof,
a phosphor, and
a density controlling agent,
wherein a weight ratio of the density controlling agent to the phosphor is about 1.5:1 to about 10:1.

2. The encapsulation material as claimed in claim 1, wherein the density controlling agent has a higher density than the first polysiloxane and the second polysiloxane.

3. The encapsulation material as claimed in claim 1, wherein the density controlling agent includes silica, a metal oxide, or a combination thereof.

4. The encapsulation material as claimed in claim 3, wherein the density controlling agent includes the metal oxide, the metal oxide including titanium oxide, zinc oxide, aluminum oxide, or a combination thereof.

5. The encapsulation material as claimed in claim 1, further comprising a dispersion aid.

6. The encapsulation material as claimed in claim 5, wherein the dispersion aid includes a silane-based compound, a (meth)acryl-based compound, or a combination thereof.

7. The encapsulation material as claimed in claim 5, wherein the dispersion aid includes trimethoxysilane, glycidyloxypropyl trimethoxysilane, mercaptopropyl trimethoxysilane, epoxycyclohexyl ethyl trimethoxysilane, trimethoxy (7-octen-1-yl)silane, oxabicyclo[4.1.0]hept-3-yl)ethyl]silane, methyltrimethoxysilane, phenyltrimethoxysilane, vinyltrimethoxysilane, allyltrimethoxysilane, 3-(trimethoxysilyl)propyl(meth)acrylate, or a combination thereof.

8. The encapsulation material as claimed in claim 6, wherein the dispersion aid is included in an amount of about 0.01 to about 5 wt %, based on a total weight of the encapsulation material.

9. The encapsulation material as claimed in claim 1, wherein:
the first polysiloxane is represented by the following Chemical Formula 1:
(R₁R₂R₃SiO_{1/2})_{M1}(R₄R₅SiO_{2/2})_{D1}(R₆SiO_{3/2})_{T1}(SiO_{4/2})_{Q1}, and [Chemical Formula 1]
in Chemical Formula 1:
R₁ to R₆ are each independently hydrogen, a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof,
at least one of R₁ to R₆ is hydrogen,
0<M1<1, 0≦D1<1, 0≦T1<1, 0≦Q1<1, and
M1+D1+T1+Q1=1.

10. The encapsulation material as claimed in claim 1, wherein:
the second polysiloxane is represented by the following Chemical Formula 2:
(R₇R₈R₉SiO_{1/2})_{M2}(R₁₀R₁₁SiO_{2/2})_{D2}(R₁₂SiO_{3/2})_{T2}(SiO_{4/2})_{Q2}, and [Chemical Formula 2]
in Chemical Formula 2:
R₇ to R₁₂ are each independently substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C1 to C30 carbonyl group, a hydroxy group, or a combination thereof,
at least one of R₇ to R₁₂ is a substituted or unsubstituted C2 to C30 alkenyl group,
0<M2<1, 0≦D2<1, 0≦T2<1, 0≦Q2<1, and
M2+D2+T2+Q2=1.

11. The encapsulation material as claimed in claim 1, wherein:
the first polysiloxane is included in an amount of less than about 50 wt % of a total weight of the resin, and
the second polysiloxane is included in an amount of more than about 50 wt % of a total weight of the resin.

12. An electronic device comprising an encapsulant prepared by curing the encapsulation material as claimed in claim 1.

13. The electronic device as claimed in claim 12, wherein the electronic device includes a light emitting region that emits light having a shorter wavelength than light emitted by the phosphor.

14. The electronic device as claimed in claim 13, wherein the device displays white color light by combining light emitted from the light emitting region and the phosphor.

15. The electronic device as claimed in claim 13, wherein the light emitting region includes one of a light emitting diode and an organic light emitting device.

16. The electronic device as claimed in claim 12, wherein:
the encapsulant includes silica, a metal oxide, or a combination thereof, and
a weight ratio of the silica, the metal oxide, or the combination thereof to the phosphor is about 1.5:1 to about 10:1.
